(19) United States
(12) Patent Application Publication
(10) Pub. No.: US 2017/0336451 A1
(43) Pub. Date: Nov. 23, 2017

(54) PROBE CARD FOR MEASURING MICRO-CAPACITANCE

(71) Applicant: MiraMEMS Sensing Technology Co., Ltd, Suzhou (CN)

(72) Inventor: YUE HONG CHEN, Hsinchu City (TW)

(21) Appl. No.: 15/599,044

(22) Filed: May 18, 2017

(30) Foreign Application Priority Data
May 19, 2016 (CN) 201610333891.1

(51) Int. Cl. G01R 27/26; B81B 7/02; G01D 5/24; B81B 3/00

(52) U.S. Cl. CPC G01R 27/2605; G01R 27/2676; B81B 3/0018; B81B 7/02; G01D 5/24

(57) ABSTRACT

A probe card for measuring micro-capacitance comprises a substrate and a capacitance-to-digital converter. The substrate has a first surface and a second surface. A plurality of conductive contacts is disposed on the first surface. A plurality of probes is disposed on the second surface. The probes are electrically connected with the corresponding conductive contacts. The capacitance-to-digital converter is disposed on the first surface and electrically connected with the corresponding conductive contacts to measure at least one micro-capacitance of an analyte and convert the micro-capacitance into a digital signal. The abovementioned probe card has an advantage of low cost.

### BACKGROUND OF THE INVENTION

### 1. Field of the Invention

The present invention relates to a probe card, particularly to a probe card for measuring micro-capacitance.

### 2. Description of the Prior Art

The concept of the microelectromechanical system (MEMS) appeared in 1970s. Nowadays, MEMS has evolved from a subject explored in laboratories into an object a high-level system usually involves and has been extensively applied to consumer electronics. The application of MEMS is still growing stably in a surprising speed. MEMS includes a microelectromechanical dynamic element realizing various functions via sensing the capacitance difference induced by dynamic physical magnitudes.

The conventional wafer-level capacitance measurement methods usually adopt a large-scale inductance-capacitance-resistance (ICR) meter or PCI eXtensions for Instrumentation (PXI). The apparatuses thereof are very expensive, and the cost of the measurement thereby is very high. There is another wafer-level capacitance measurement method assembling AC signal sources, voltage-control amplifiers, power amplifiers into a complicated circuit on a wafer test substrate. However, the development and maintenance of the test substrate is considerably difficult. For example, different MEMS devices need different test substrates, which must be developed specially, i.e. customized. Thus, the cost of the measurement using the latter method is also very high.

Therefore, a test substrate easy to develop and maintain is a target the manufacturers are eager to achieve.

### SUMMARY OF THE INVENTION

The present invention provides a probe card for measuring micro-capacitance, wherein a capacitance-to-digital converter (CDC) is installed on a standard substrate supplied by the test industry. Both the CDC and the standard substrate are existing elements, which needn't be developed extra. Therefore, the present invention can significantly decrease the cost of developing and maintaining probe cards

In one embodiment, the present invention proposes a probe card for measuring micro-capacitance, which comprises a substrate and a capacitance-to-digital converter (CDC). The substrate has a first surface and a second surface. A plurality of conductive contacts is disposed on the first surface. A plurality of probes is disposed on the second surface, contacting a plurality of test contacts of an analyte. The probes are electrically connected with the corresponding conductive contacts. The CDC is disposed on the first surface of the substrate and electrically connected with the corresponding conductive contacts to measure at least one micro-capacitance of the analyte and convert the micro-capacitance into a digital signal.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a diagram schematically showing a probe card for measuring micro-capacitance according to one embodiment of the present invention; and

FIG. 2 is a diagram schematically showing a parasitic capacitance existing between two leads.

### DESCRIPTION OF THE PREFERRED EMBODIMENTS

The present invention will be described in detail with embodiments and attached drawings below. However, these embodiments are only to exemplify the present invention but not to limit the scope of the present invention. In addition to the embodiments described in the specification, the present invention also applies to other embodiments. Further, any modification, variation, or substitution, which can be easily made by the persons skilled in that art according to the embodiment of the present invention, is to be also included within the scope of the present invention, which is based on the claims stated below. Although many special details are provided herein to make the readers more fully understand the present invention, the present invention can still be practiced under a condition that these special details are partially or completely omitted. Besides, the elements or steps, which are well known by the persons skilled in the art, are not described herein lest the present invention be limited unnecessarily. Similar or identical elements are denoted with similar or identical symbols in the drawings. It should be noted: the drawings are only to depict the present invention schematically but not to show the real dimensions or quantities of the present invention. Besides, matterless details are not necessarily depicted in the drawings to achieve conciseness of the drawings.

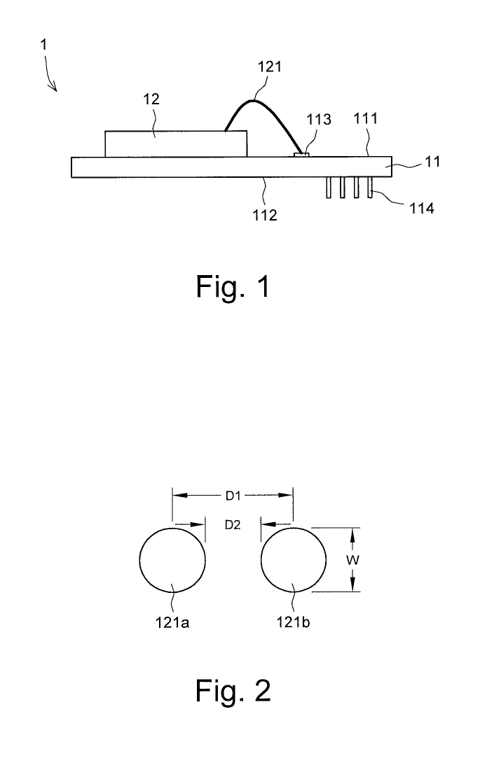

Refer to FIG. 1. In one embodiment, the probe card 1 for measuring micro-capacitance of the present invention comprises a substrate 11 and a capacitance-to-digital converter (CDC) 12. The substrate 11 has a first surface 111 and a second surface 112. A plurality of conductive contacts 113 is disposed on the first surface 111 of the substrate 11. A plurality of probes 114 is disposed on the second surface 112 of the substrate 11. The probes 114 are to contact a plurality of test contacts of an analyte, such as a wafer, whereby the probes 114 are electrically connected with the analyte. In one embodiment, the analyte is a wafer-level MEMS sensor, wherein a plurality of MEMS sensors is fabricated on a wafer. The probes 114 on the second surface 112 are electrically connected with the corresponding conductive contacts 113 on the first surface 111. For example, the probes 114 are electrically connected with the corresponding conductive contacts 113 via internal interconnection lines of the substrate 11. In one embodiment, the substrate 11 is a standard substrate supplied by the test industry.

The standard substrate is a fixed-specification temporary substrate that the test industry supplies to other industries for developing and testing the substrate, i.e. the so-called evaluation reference board (ERB). After the development is completed, a customized test substrate is fabricated according to the developed prototype test substrate. In other words, the measurement in the production line is undertaken with the customized test substrate. As the standard substrates are of a fixed specification, the test industry would mass-produce them to reduce the cost. In other words, the fabrication cost of standard substrates is much lower than that of customized substrates. Different test industries respectively provide standard substrates for their own test platforms. Therefore, the standard substrates supplied by different test industries may be of different specifications.

The CDC 12 is disposed on the first surface 111 of the substrate 11. At present, the CDC 12 is normally applied to the capacitance measurement of capacitive-type touch control devices, not to the reliability test of electronic elements. The CDC 12 is electrically connected with the corresponding conductive contacts 113. For example, the CDC 12 is electrically connected with the corresponding conductive contacts 113 through a plurality of leads 121. The CDC 12 is further electrically connected with the test contacts of the analyte through the corresponding conductive contacts 113 to measure at least one micro-capacitance of the analyte and convert the micro-capacitance into a digital signal. In one embodiment, the CDC 12 can measure a capacitance within +4 pF and can tolerate a parasitic capacitance less than 60 pF.

As the substrate 11 is a standard substrate of a fixed specification, the CDC 12 is normally electrically connected with the substrate 11 via the leads 121. Refer to FIG. 2. A parasitic capacitance may exist between the lead 121a and the lead 121b. The parasitic capacitance may be estimated with a plate capacitor equation:

C=ε×A/d

wherein C is the capacitance, a the dielectric coefficient, A the relative area of the plate capacitor, and d the distance between the plates. In the case shown in FIG. 2, the distance between the plates is within a distance D1 and a distance D2, wherein D1 is the distance between the centers of the leads 121a and 121b, and D2 is the shortest distance between the surfaces of the leads 121a and 121b; the relative area A is equal to a product of a width W of the lead 121a or 121b and a length of the lead 121a or 121b. It is easily understood: the shorter the leads, the smaller the parasitic capacitance. In one embodiment, the length of the leads is smaller than or equal to 5 cm. It is preferred: the length of the electric-conduction path between the CDC 12 and the probes 114 is smaller than or equal to 5 cm. Subtracting the parasitic capacitance between the leads 121a and 121b from the measured capacitance will get a more accurate measurement result.

In conclusion, the present invention proposes a probe card for measuring micro-capacitance, wherein the CDC is disposed on a standard substrate supplied by the test industry to measure micro-capacitance. As the CDC and the standard substrate are existing elements, it is unnecessary to develop them specially. Thereby, the cost of developing and maintaining the probe card of the present invention is obviously lower than that of the conventional probe card.

What is claimed is:

1. A probe card for measuring micro-capacitance, comprising
a substrate having a first surface and a second surface, wherein a plurality of conductive contacts is disposed on said first surface of said substrate, and wherein a plurality of probes is disposed on said second surface of said substrate to contact a plurality of test contacts of an analyte, and wherein said probes are respectively electrically connected with corresponding said conductive contacts; and
a capacitance-to-digital converter disposed on said second surface of said substrate and electrically connected with corresponding said conductive contacts to measure at least one micro-capacitance of said analyte and convert said micro-capacitance into a digital signal.

2. The probe card for measuring micro-capacitance according to claim 1, wherein said substrate is a standard substrate.

3. The probe card for measuring micro-capacitance according to claim 1, wherein said capacitance-to-digital converter is electrically connected with corresponding said conductive contacts via a plurality of leads.

4. The probe card for measuring micro-capacitance according to claim 3, wherein a length of said leads is smaller than or equal to 5 cm.

5. The probe card for measuring micro-capacitance according to claim 1, wherein a length of an electric-conduction path between said capacitance-to-digital converter and said probes is smaller than or equal to 5 cm.

6. The probe card for measuring micro-capacitance according to claim 1, wherein said capacitance-to-digital converter can measure a capacitance within ±4 pF.

7. The probe card for measuring micro-capacitance according to claim 1, wherein said capacitance-to-digital converter can tolerate a parasitic capacitance less than 60 pF.

8. The probe card for measuring micro-capacitance according to claim 1, wherein said analyte is a wafer.

9. The probe card for measuring micro-capacitance according to claim 1, wherein said analyte is a wafer-level microelectromechanical sensor.
